(19) United States
(12) Patent Application Publication
(10) Pub. No.: US 2008/0070360 A1
(43) Pub. Date: Mar. 20, 2008

(54) METHOD AND STRUCTURE FOR FORMING SILICIDE CONTACTS ON EMBEDDED SILICON GERMANIUM REGIONS OF CMOS DEVICES

(75) Inventors: Oh-Jung Kwon, Hopewell Junction, NY (US); O Sung Kwon, Wappingers Falls, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/533,018

(22) Filed: Sep. 19, 2006

(51) Int. Cl. H01L 21/8238

(52) U.S. Cl. 438/233

(57) ABSTRACT

A method of forming silicide contacts for a complementary metal oxide semiconductor (CMOS) device includes selectively forming a protective layer over faceted surfaces of an embedded SiGe (eSiGe) region of a substrate, the eSiGe region comprising a compressive stress inducing layer in a PFET portion of the CMOS device, wherein the faceted surfaces are disposed adjacent shallow trench isolation (STI) regions used to separate NFET regions from PFET regions of the CMOS device; depositing a metal layer for silicide formation over the CMOS device; and annealing the CMOS device to form silicide, wherein the protective layer formed over the faceted surfaces prevents the formation of silicide thereon.

### BACKGROUND

The present invention relates generally to semiconductor device processing techniques and, more particularly, to a method and structure for forming silicide contacts on embedded silicon germanium (eSiGe) regions of CMOS devices.

Silicide contacts are of specific importance to integrated circuits, including those having complementary metal oxide semiconductor (CMOS) devices, because of the need to reduce the electrical resistance of the contacts (particularly at the source/drain and gate regions) in order to increase chip performance. Silicides are metal compounds that are thermally stable and provide for low electrical resistivity at the silicon/metal interface. Reducing contact resistance improves device speed, therefore increasing device performance.

Silicide formation typically requires depositing a metal such as Ni, Co, Pd, Pt, Rh, Ir, Zr, Cr, Hr, Er, Mo or Ti onto the surface of a silicon-containing material or wafer. Following deposition, the structure is then subjected to an annealing step using conventional processes such as, but not limited to, rapid thermal annealing. During thermal annealing, the deposited metal reacts with silicon to form a metal silicide. Portions of the metal not formed atop silicon are not reacted during the anneal, and may thus be thereafter selectively removed with respect to the reacted silicide.

In CMOS devices, both n-type field effect transistors (NFET) and p-type field effect transistors (PFET) are combined in the same structure. Since it has become increasingly difficult to improve MOSFETs (and therefore CMOS device performance) through continued scaling, methods for improving performance without scaling have become critical. One recently implemented approach for doing this is to increase carrier (electron and/or hole) mobilities by introducing an appropriate strain into the silicon lattice. The application of stresses or strains changes the lattice dimensions of the silicon-containing substrate. By changing the lattice dimensions, the energy gap of the material is changed as well. When a semiconducting material is doped (e.g., n-type) and partially ionized, a very small change in the energy bands can cause a large percentage change in the energy difference between the impurity levels and the band edge. Thus, the change in resistance of the material with stress is large.

In terms of the direction of the stress versus the polarity of the dopant, NFET devices require a tensile stress on the channel for strain-based carrier mobility (electron) improvement, while PFET need a compressive stress on the channel for strain-based carrier mobility (hole) improvement. In the particular case of PFET devices, the use of embedded SiGe (eSiGe) structures is one manner of facilitating a compressive stress on the channel. In the manufacture of such structures, a cavity is created in the active area of the PFET device following gate stack definition, spacer formation and dopant implantation (the NFET devices simultaneously being protected by a suitable layer, such as a hardmask). The cavity is thereafter filled with epitaxially grown SiGe material, which may be in-situ doped with a material such as boron.

However, during the formation of an embedded SiGe structure, the SiGe may typically be overgrown in the cavity such that a facet is created at the edge of the active area of the transistor, adjacent a shallow trench isolation (STI) region. With respect to the silicidation process discussed above, such faceting can result in the silicide material protruding deeper into the silicon substrate, such as shown in the SEM image of FIG. 1, for example. This in turn causes undesirable junction leakage current, and adversely affects device performance. Accordingly, it would be desirable to be able to prevent such adverse effects due to silicidation of strain engineered PFET devices of the eSiGe type.

### SUMMARY

The foregoing discussed drawbacks and deficiencies of the prior art are overcome or alleviated by a method of forming silicide contacts for a complementary metal oxide semiconductor (CMOS) device. In an exemplary embodiment, the method includes selectively forming a protective layer over faceted surfaces of an embedded SiGe (eSiGe) region of a substrate, the eSiGe region comprising a compressive stress inducing layer in a PFET portion of the CMOS device, wherein the faceted surfaces are disposed adjacent shallow trench isolation (STI) regions used to separate NFET regions from PFET regions of the CMOS device; depositing a metal layer to form silicide over the CMOS device; and annealing the CMOS device, wherein the protective layer formed over the faceted surfaces prevents the formation of silicide thereon.

In another embodiment, a complementary metal oxide semiconductor (CMOS) device includes at least one NFET device and at least one PFET device formed on a semiconductor substrate; a protective layer formed over faceted surfaces of an embedded SiGe (eSiGe) region of the PFET device, the eSiGe region comprising a compressive stress inducing layer, wherein the faceted surfaces are disposed adjacent shallow trench isolation (STI) regions used to separate NFET regions from PFET regions of the CMOS device; and a plurality of silicide contacts for the at least one NFET device and the at least one PFET device, wherein the protective layer formed over the faceted surfaces prevents the formation of silicide thereon.

### Technical Effects

As a result of the summarized invention, a solution is technically achieved in which an embedded SiGe transistor is silicided by selectively forming a protective layer over faceted portions of the eSiGe regions, thereby preventing formation of silicide on the faceted portions and eliminating the protrusion silicide material into the silicon substrate adjacent STI regions, which in turn prevents undesirable junction leakage current.

### BRIEF DESCRIPTION OF THE DRAWINGS

Referring to the exemplary drawings wherein like elements are numbered alike in the several Figures:

FIG. 1 is a scanning electron microscope (SEM) image of a silicided CMOS device, particularly illustrating an eSiGe region used for compressive tension in the PFET device;

FIGS. 2(a) through 2(e) illustrate a sequence of process flow diagrams of a method for forming silicide contacts on eSiGe regions of CMOS devices, in accordance with an exemplary embodiment of the invention;

FIGS. 3(a) through 3(c) illustrate an alternative process for forming the protective oxide on the faceted surfaces of the eSiGe regions, in accordance with another exemplary embodiment of the invention; and

FIG. 4 is an SEM image of a silicided eSiGe region using the exemplary method embodiments disclosed herein.

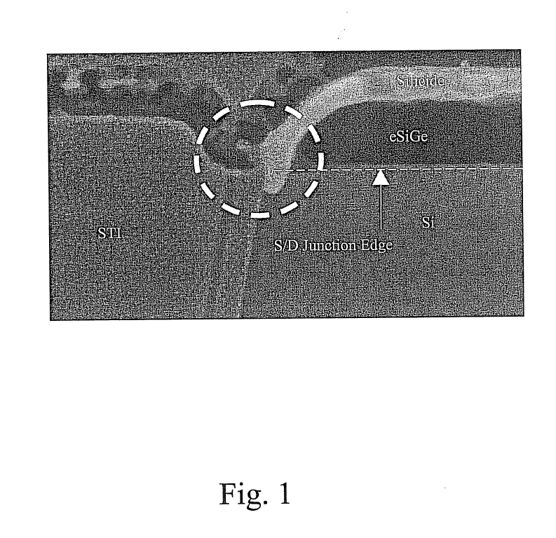

### DETAILED DESCRIPTION

Disclosed herein is a method and structure for forming silicide contacts on eSiGe regions of CMOS devices. Briefly stated, a protective layer (e.g., oxide) is selectively formed on faceted regions of the eSiGe adjacent the STI regions prior to deposition of a metal layer for silicide formation. Therefore, during the anneal step, the metal does not react to form silicide over the faceted regions, thereby preventing silicide from penetrating deeper into the silicon substrate and adversely affecting junction leakage current.

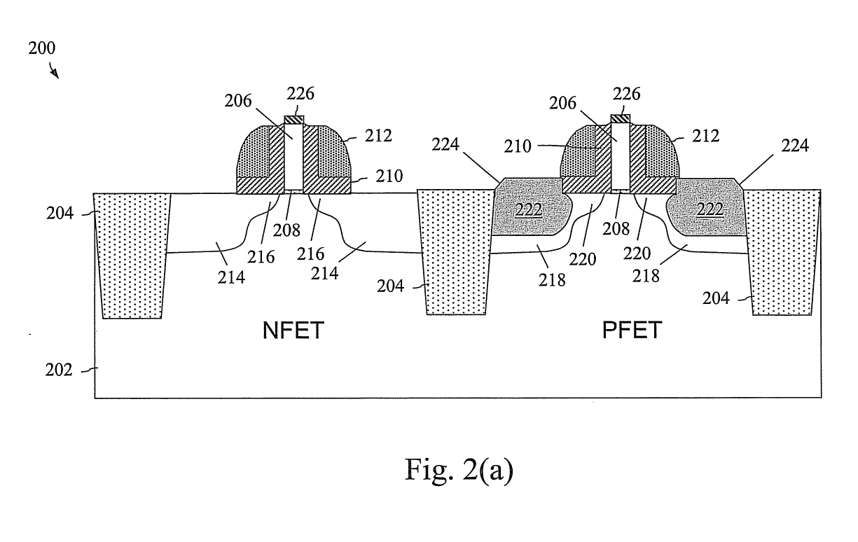

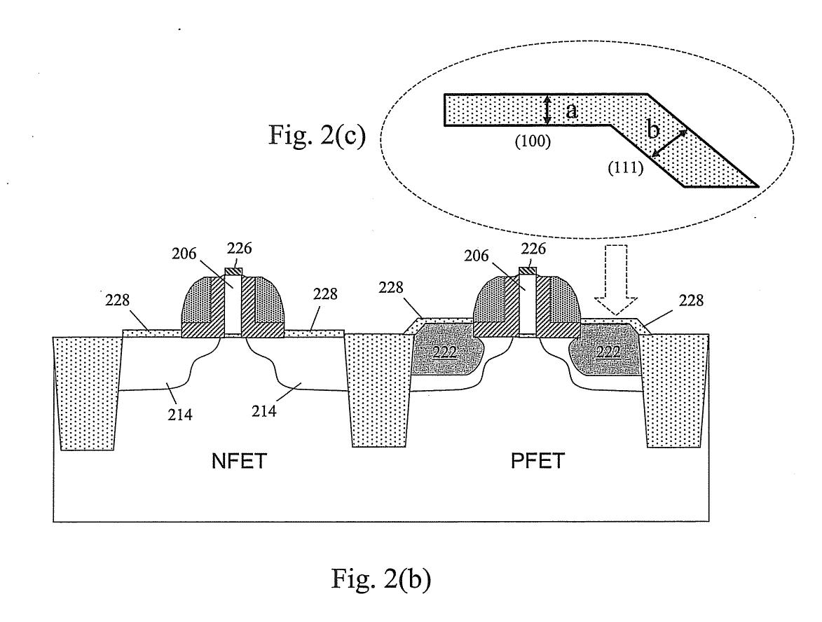

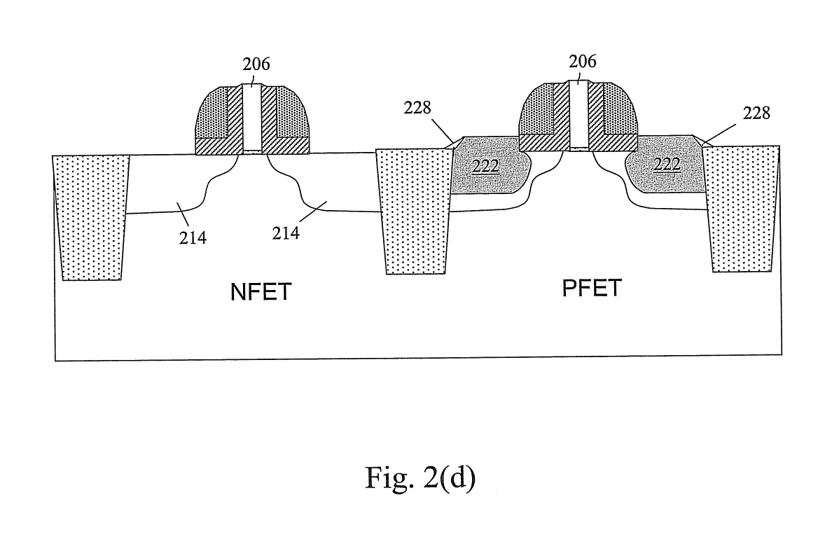

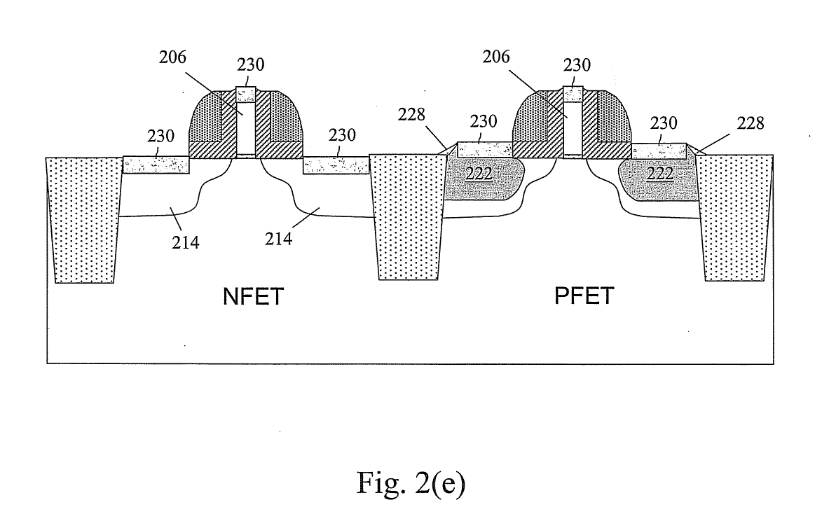

FIGS. 2(a) through 2(e) illustrate a sequence of process flow diagrams of a method for forming silicide contacts on eSiGe regions of CMOS devices, in accordance with an exemplary embodiment of the invention. At the outset, FIG. 2(a) depicts a CMOS device 200 at in point in processing following the definition of NFET and PFET device regions (labeled “NFET” and “PFET” in the Figures) in a substrate 202 of silicon containing material. A plurality of STI regions 204 (e.g., oxide filled trenches) are formed for separating the PFET region from the NFET region. It will be noted that although FIG. 2(a) depicts a single PFET device and a single NFET device in the PFET and NFET regions, multiple such devices can exist in actuality.

The NFET and PFET devices may be initially formed through existing processing steps that are capable of fabricating MOSFET devices. In particular, each device includes a gate conductor 206 (e.g., polysilicon) formed on a gate insulating layer 208 (e.g., oxide). At least one set of sidewall spacers 210, 212 may be located adjacent the gate region (i.e., gate conductor 206 and gate insulating layer 208). NFET source/drain regions 214, including extension regions 216, are defined within the NFET portion of the substrate 202 and define an NFET device channel. The NFET source/drain regions 214 and extension regions 216 are doped with a suitable n-type dopant material (e.g., As, Sb, P, N). Similarly, PFET source/drain regions 218, including extension regions 220, are defined within the PFET portion of the substrate 202 and define a PFET device channel. The PFET source/drain regions 218 and extension regions 220 are doped with a suitable p-type dopant material (e.g., In, Ga, Al, B).

In accordance with certain strain engineering techniques described above, the device 200 of FIG. 2(a) is further processed so as to create embedded SiGe (eSiGe) regions 222 within recessed portions of the PFET source/drain and extension regions 218,-220. As also indicated above, the compressive strain producing SiGe material 222 is nominally grown in a manner so as to overfill the top of the substrate 202 and adjacent STI regions 204. In so doing, a faceted surface 224 is formed at the edge of the active area adjacent the STI regions 204. Whereas the planar portions of the top surfaces of the SiGe material are within the (100) crystallographic plane, the faceted surface 224 is within the (111) crystallographic plane of the material. In addition to overfilling the top of the substrate, the process of filling eSiGe to the top of the substrate can also result in faceted surfaces of eSiGe.

At the point of processing shown in FIG. 2(a), a cap nitride layer 226 atop the gate conductors 206 would ordinarily be removed to facilitate conventional silicide processing of the CMOS devices. However, in the present embodiments, the cap nitride layer 226 (used for a prior reactive ion etch step) is temporarily left in place, as will be appreciated hereinafter.

Referring now to FIG. 2(b), the CMOS device is now subjected to a selective oxidation process (e.g., by thermal anneal) that forms an oxide layer 228 on the exposed silicon surfaces of the device. This includes NFET source/drain regions 214 and eSiGe regions 222 of the PFET device. Notably, the nitride cap layer 226 prevents the oxide formation on the polysilicon gate conductors 206 of both the NFET and PFET devices.

Because the NFET source/drain regions 214 are substantially planar, the oxide layer 228 thereon is of substantially uniform thickness. In contrast, the portions of the oxide layer 228 over the eSiGe regions 222 are formed anisotropically with respect to the faceted surfaces. As specifically shown in the insert view of FIG. 2(c), it will be seen that the oxidation rate on the faceted surfaces of the eSiGe material in the (111) crystallographic plane is greater than the oxidation rate on the horizontal, planar surfaces in the (100) crystallographic plane. Consequently, the thickness “a” of the oxide formed over the planar portion of the eSiGe material is less than the thickness “b” of the oxide formed over the faceted portion of the eSiGe material.

As then shown in FIG. 2(d), the oxide layer 228 over the horizontal planar surfaces is removed, so as to remain only upon the faceted surfaces of the eSiGe material 222. This may be done, for example, through either an isotropic etch or an anisotropic etch (preferred), wherein a target thickness removal is between dimensions “a” and “b” depicted in FIG. 2(c). As a practical matter, some STI material will also be removed during this process. Thereafter, the cap nitride layer atop gate conductors 206 may be removed, as also reflected in FIG. 2(d). Thereby, the CMOS device is now prepared for silicidation, with the faceted surfaces of eSiGe regions 222 being protected by oxide layer 228 to prevent silicidation thereof. Finally, FIG. 2(e) illustrates the formation of silicide contacts 230 over the planar surfaces of the gate conductors 206, NFET source/drain regions 214 and PFET eSiGe regions 222 (by suitable metal layer deposition and thermal anneal as described previously).

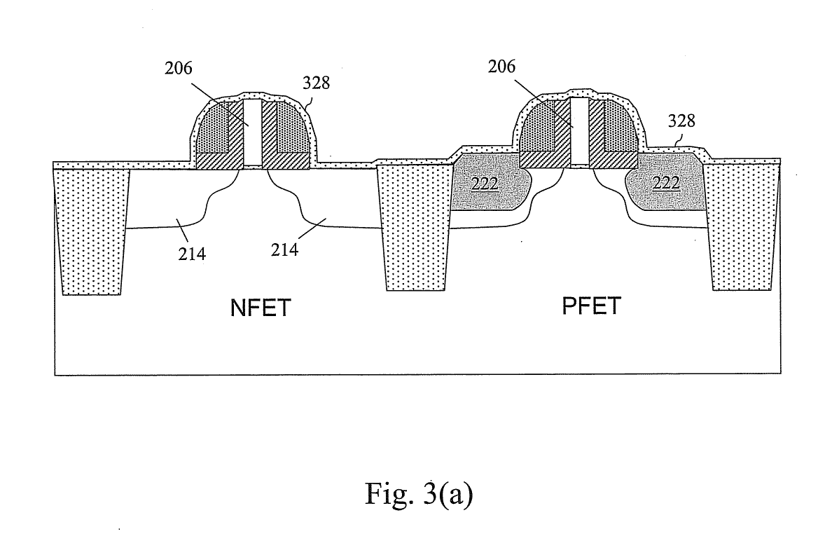

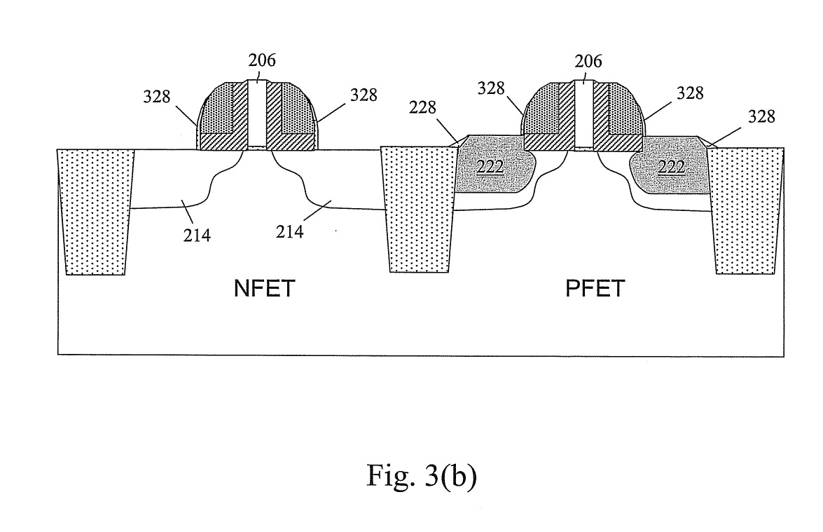

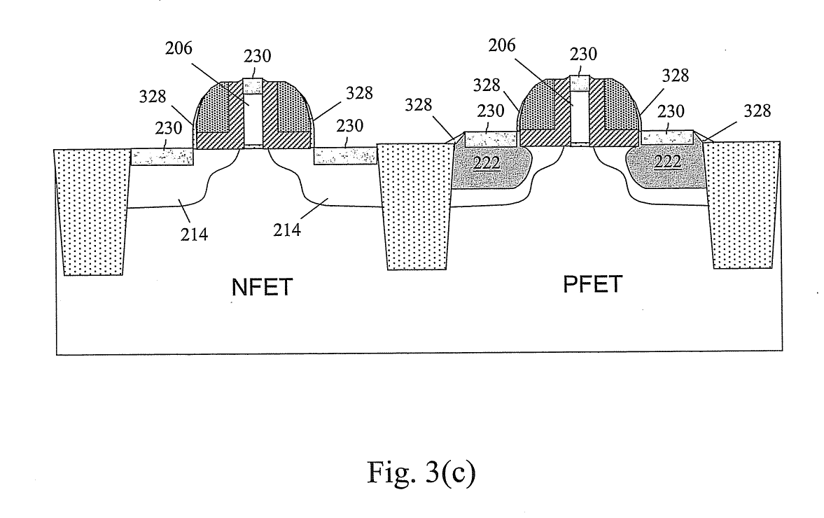

It will be appreciated that the selective oxide formation at different growth rates on faceted (111) plane surfaces of SiGe represents one exemplary manner of preventing silicide growth thereon. For example, FIGS. 3(a) through 3(c) illustrate an alternative process for forming a protective oxide on the faceted surfaces of the eSiGe regions, in accordance with another exemplary embodiment of the invention. As shown in FIG. 3(a), a conformal oxide layer 328 is blanket deposited over the entire surface of the device, including the gate conductors 206, NFET source/drain regions 214 and PFET eSiGe regions 222.

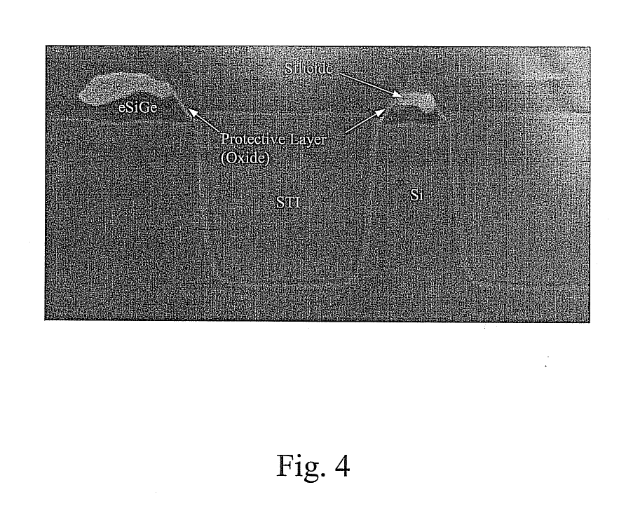

Then, in FIG. 3(b), the conformal oxide layer 328 is directionally (anisotropically) etched so as to be removed from the planar surfaces of the CMOS device. As a result, an amount of the oxide layer 328 is left on the faceted surfaces of the eSiGe regions 222 (as a small amount on the gate sidewall spacers) of both the NFET and PFET devices. Thus protected, the silicidation steps of metal deposition and anneal are implemented so as to form the silicide contacts shown in FIG. 3(c). As is the case for the embodiment of FIGS. 2(a) through 2(e), conformal deposition of a protective oxide layer followed by selective removal of the oxide on planar surfaces protects the faceted portions of eSiGe regions at the edge of the active area from silicidation. FIG. 4 is an SEM image illustrating the use of a protective oxide for prevention of silicide formation on faceted surfaces of eSiGe.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method of forming silicide contacts for a complementary metal oxide semiconductor (CMOS) device, the method comprising:
selectively forming a protective layer over faceted surfaces of an embedded SiGe (eSiGe) region of a substrate, the eSiGe region comprising a compressive stress inducing layer in a PFET portion of the CMOS device, wherein the faceted surfaces are disposed adjacent shallow trench isolation (STI) regions used to separate NFET regions from PFET regions of the CMOS device;
depositing a metal layer for silicide formation over the CMOS device; and
annealing the CMOS device to form silicide, wherein the protective layer formed over the faceted surfaces prevents the formation of silicide thereon.

2. The method of claim 1, wherein the protective layer comprises an oxide material.

3. The method of claim 2, wherein the protective oxide material is formed by selective oxidation of silicon containing surfaces, including the eSiGe region, and wherein an oxidation rate of the faceted surfaces of the eSiGe region is greater than horizontal surfaces of the eSiGe region.

4. The method of claim 3, further comprising removing portions of the protective oxide material formed on the horizontal surfaces of the eSiGe region while maintaining at least a portion of the protective oxide material on the faceted surfaces of the eSiGe region.

5. The method of claim 4, wherein:
the protective oxide material formed on the horizontal surfaces of the eSiGe region are initially formed at a first thickness;
the protective oxide material formed on the faced surfaces of the eSiGe region are initially formed at a second thickness greater than the first thickness; and
an etch process used to remove the protective oxide material from the horizontal surfaces of the eSiGe region is targeted for a thickness between the first and second thicknesses.

6. The method of claim 2, wherein the protective oxide material is formed by conformal deposition of an oxide layer over the CMOS device followed by a directional etch of the oxide layer.

7. The method of claim 1, wherein the faceted surfaces of the eSiGe region corresponds to the (111) crystallographic plane, and wherein horizontal surfaces of the eSiGe region correspond to the crystallographic plane (100).

8. A complementary metal oxide semiconductor (CMOS) device, comprising:
at least one NFET device and at least one PFET device formed on a semiconductor substrate;
a protective layer formed over faceted surfaces of an embedded SiGe (eSiGe) region of the PFET device, the eSiGe region comprising a compressive stress inducing layer, wherein the faceted surfaces are disposed adjacent shallow trench isolation (STI) regions used to separate NFET regions from PFET regions of the CMOS device; and
a plurality of silicide contacts for the at least one NFET device and the at least one PFET device, wherein the protective layer formed over the faceted surfaces prevents the formation of silicide thereon.
